(19) United States
(12) Patent Application Publication
(10) Pub. No.: US 2020/0324296 A1
(43) Pub. Date: Oct. 15, 2020

(54) Lining Plate of Multi-Gradient Structure-Reinforced Cone Crusher and Design Method Thereof

(71) Applicant: JIANGXI UNIVERSITY OF SCIENCE AND TECHNOLOGY, Ganzhou (CN)

(72) Inventors: Gaipin CAI, Ganzhou (CN); Zhihong JIANG, Ganzhou (CN); Shun NIAN, Ganzhou (CN); Chunsheng GAO, Ganzhou (CN); Dongyang HU, Ganzhou (CN); Jianli WANG, Ganzhou (CN); Lianhua ZHANG, Ganzhou (CN); Gangxiang LIU, Ganzhou (CN)

(21) Appl. No.: 16/842,992

(22) Filed: Apr. 8, 2020

(30) Foreign Application Priority Data
Apr. 10, 2019 (CN) 201910283628.X

(51) Int. Cl. B02C 2/00; G06F 30/10; G06F 30/25

(52) U.S. Cl. CPC B02C 2/005; G06F 30/25; G06F 30/10

(57) ABSTRACT

The present disclosure discloses a multi-gradient structure-reinforced cone crusher and a design method of a lining plate thereof. The multi-gradient structure-reinforced cone crusher includes a movable cone and a fixed cone arranged around the movable cone, and a crushing cavity formed in the radial space between the fixed cone and the movable cone, the surfaces of the fixed cone and the movable cone that are opposite to each other are respectively provided with a fixed cone lining plate and a movable cone lining plate, the working faces of the fixed cone lining plate and the movable cone lining plate that face the crushing cavity are provided with multiple sets of cast-in alloy, which are different in at least one of distribution density, maximum size of exposed surface and shape of the cast-in alloy in a direction from the feed port to the discharge port.

### CROSS REFERENCE TO RELATED APPLICATIONS

This application claims priority to Chinese Application No. 201910283628.X, filed on Apr. 10, 2019, entitled “Lining Plate of Multi-Gradient Structure-Reinforced Cone Crusher and Design Method Thereof”, which is specifically and entirely incorporated by reference.

### FIELD OF THE INVENTION

The present disclosure belongs to the technical field of design of cone crushing equipment, in particular relates to a multi-gradient structure-reinforced cone crusher and a lining plate of multi-gradient structure-reinforced cone crusher; in addition, the present disclosure further relates to a design method of a lining plate of multi-gradient structure-reinforced cone crusher.

### BACKGROUND OF THE INVENTION

The working mechanism of a cone crusher consists of a crushing wall and a rolling mortar wall, wherein the crushing wall is mounted eccentrically in the middle of the rolling mortar wall via a main shaft in it, and the crushing wall can oscillate with respect to the rolling mortar wall. In the swing process, the crushing wall crushes the material in the crushing cavity so that the particle diameter of the ore is decreased continuously, till the material is crushed to a specific particle diameter and then discharged out of the crushing cavity.

At present, the crushers used in the crushing industry in China are mainly categorized into two categories: one category of crushers are traditional spring cone crushers, which utilize a movable cone to obtain large displacement and great crushing force for pressing and crushing materials; these crusher have low crushing efficiency because the rotation speed of the movable cone is low and the crushing cavity is a conventional inverted cone cavity structure; the other category of crushers are imported crushers, represented by Sandvik and Metso crushers, which have high installed capacity, employ a movable cone operating at a high rotation speed, and employ a laminating crushing cavity structure; therefore, these crushers have high crushing efficiency, but the lining plate is worn quickly, and the operating cost of the equipment is severely increased.

The crushing capacity and discharging granularity of a cone crusher are closely related with the geometric structure of the crushing cavity and the geometric structure of the crushing wall and rolling mortar wall; the consistency of crushing cavity shape in early stage and late stage and the service life of the crushing wall and rolling mortar wall are related with the structure of the crushing cavity, geometric structure of the lining plate, and material composition of the lining plate.

At present, conical crushing cavities are mainly designed into V-shaped crushing cavities, with the working face of the lining plate in a simple shape, according to coarse crushing, medium crushing, and fine crushing granularities and crushing ratios of the fed material, under a condition that the angle of engagement doesn't exceed 25°; owing to the fact the ore is detained in such a crushing cavity for a short time and is subjected to a simple load, the material can't be crushed selectively; moreover, the crushing load is higher and the lining plate is worn more quickly at a position nearer the bottom of the crushing cavity; therefore, since the lining plates are made of a high manganese steel alloy material solely at present, the shape of the crushing cavity will change quickly in the early stage and late stage of use of the lining plate.

Patents related with the technique in the present disclosure mainly include:

The patent document No. CN02267731.3 titled as “Teeth-Inserted Lining Plate of Crusher” has disclosed an teeth-inserted lining plate, which is composed of a lining plate body and crushing teeth, which are separate structures, wherein the lining plate body has a groove in its inner wall, while the crushing teeth have a tongue on their back, and the tongue of the crushing teeth is fitted in the groove of the lining plate body to form a teeth-inserted lining plate. The body part of the lining plate in such a structure can be reused, and the lining plate becomes a new one after worn crushing teeth are replaced. However, the lining plate in such a teeth-inserted structure must have enough thickness; otherwise the strength of the teeth-inserted lining plate may be unable to meet the requirement under the crushing conditions.

The patent document No. CN201220695220.7 titled as “Lining Plate Structure of Cone Crusher” has disclosed a structure with a fixed cone lining plate and a movable cone lining plate, and a crushing cavity structure; the fixed cone lining plate is fitted around the movable cone lining plate, a crushing cavity is formed between the fixed cone lining plate and the movable cone lining plate, the inner wall of the fixed cone lining plate is provided with an annular groove, and the discharge end of the movable cone lining plate is provided with an outer chamfer; the contour line formed by the inner surface and annular groove of the fixed cone lining plate is a constant curve, the wear of the lining plate is uniform, and the shape of the crushing cavity remains unchanged even if the lining plate is worn. However, the patent only has disclosed the structural features of the lining plate and the crushing cavity, but hasn't disclosed a design method for the lining plate and the crushing cavity structure, and the wearing life of the lining plate and the crushing cavity structure; in addition, since the lining plate structure is made of a single material, the shapes of the bottom crushing cavity and the parallel region vary much after a time period of wearing.

The patent document No. CN201420128037.8 titled as “Composite Lining Plate of Cone Crusher” has disclosed a fixed cone lining plate body and a movable cone lining plate body, which are made of composite metal materials. Alloy strips are cast on the wearing portions of the working faces of the fixed cone lining plate body and the movable cone lining plate body (i.e., an alloy strip A is cast on the outer wall of the movable cone lining plate body, and an alloy strip B is coast on the inner wall of the fixed cone lining plate body), to enhance the wearing resistance of the lining plates and prolong the service life of the lining plates. However, the patent document hasn't disclosed how to optimize the layout of the alloy strips to keep constant the shape of the crushing cavity; the patent document hasn't disclosed how to optimize the crushing cavity structure to improve the crushing efficiency, either.

The patent document No. CN 201510272771.0 titled as “Method for Laser Dot Matrix Fused Strengthening of Rolling Mortar Wall and Crushing Wall of Cone Crusher” has disclosed a laser strengthening processing technique for the working surface of a crusher. The technique mainly utilizes a pneumatic spray gun to spray a pretreatment coating on the rolling mortar wall and crushing wall of the cone crusher, performs laser scanning pretreatment with a laser processing system, sprays a light absorbing coating on the pretreated substrate in the working region with the pneumatic spray gun, spray a light absorbing coating on the substrate in the working regions of the rolling mortar wall and the crushing wall that are pretreated with laser, and performs laser dot matrix fused scanning with a high-power solid state laser processing system to form laser fused strengthening points. Thus, the technique effectively avoids the problem of cracking under local impact, and improves the service life of the rolling mortar wall and crushing wall of the cone crusher. However, with the patented technique, only strengthening points in 3 mm diameter and 2.5˜3.5 mm depth can be formed on the working surface of the lining plate, and it is difficult for the small-area strengthening points to meet the requirement of high-hardness, high-toughness, and self-sharpening ore crushing for a long time; the surface laser strengthening process has high requirements and limited adaptability; in addition, this patent involves the same problems as the patent No. CN 201410308498.8.

The patent document No. CN201510726850.4 titled as “Wear-Resistant Lining Plate of Cone Crusher” has disclosed a method for optimizing the design of the material composition of the lining plate of a cone crusher, which makes the ratio of the elements more reasonable, so that the elements attain a synergetic effect, and the lining plate obtains improved hardness, toughness, and impact and wear resistance. In addition, the wear resistance of the lining plate is greatly improved through an intermediate frequency furnace melting process and an appropriate heat treatment process. Thus, the lining plate has an improved service life equal to 2-3 times of the service life of a lining plate made of a common steel or iron wear-resistant material, and can meet the working requirement of medium-size or large-size cone crushers. However, the patent involves the same problems as the patent No. CN201220695220.7 and the patent No. CN201410308498.8.

The patent document No. CN 201621380419.5 titled as “Ceramic Composite Lining Plate of Cone crusher” has disclosed a lining plate that comprises a rolling mortar wall, a crushing wall, and ceramic blocks, wherein the ceramic blocks are cast in the inner surface of the rolling mortar wall and the outer surface of the crushing wall; and the ceramic blocks are bonded with the rolling mortar wall and the crushing wall by metallurgical bonding. By casting a ceramic material in the manganese steel substrate of the lining plate, the wear resistance of the lining plate can be improved, and the service life of the lining plate can be prolonged. However, the ceramic material can't endure high crushing impact force since it is a brittle material; in addition, the patent involves the same problems as the patent No. CN 201220695220.7 and the patent No. CN201410308498.8.

The above-mentioned patented techniques related with the present disclosure improve the service life of the lining plate simply by casting an alloy, without considering how to improve the crushing efficiency by means of the structural design of a multi-gradient inter-particle crushing cavity, how to solve the problem of change of the crushing cavity structure resulted from non-uniform wearing of the lining plate at different height positions of the crushing cavity by employing a multi-gradient wear resistance design utilizing cast-in components different in shape, dimensions, and cast-in density, and how to solve the problem of gradually degraded quality of the crushed product.

### SUMMARY OF THE INVENTION

To overcome the drawbacks in the prior art, the present disclosure provides a multi-gradient structure-reinforced cone crusher having multiple sets of cast-in alloy different in cast-in density, layout, and shape, and a design method of a lining plate thereof, which has prolonged service life and improved crushing efficiency.

The technical scheme of the present disclosure is as follows:

A multi-gradient structure-reinforced cone crusher, comprising:

a movable cone and a fixed cone arranged around the movable cone, and a crushing cavity formed in the radial space between the fixed cone and the movable cone, wherein the surfaces of the fixed cone and the movable cone that are opposite to each other are respectively provided with a fixed cone lining plate and a movable cone lining plate;

the working faces of the fixed cone lining plate and the movable cone lining plate that face the crushing cavity are provided with multiple sets of cast-in alloy, which are different in at least one of distribution density, maximum size of exposed surface, and shape of the cast-in alloy in a direction from the feed port to the discharge port.

Preferably, the working faces of the fixed cone lining plate and the movable cone lining plate are stepped curve surfaces surrounding the rotating axis of the movable cone respectively, and the generatrix of the stepped curve surface comprises a plurality of broken line segments, so that the crushing cavity is formed into multiple levels of sub-crushing cavities, the multiple levels of sub-crushing cavities comprise an upper sub-crushing cavity, a middle sub-crushing cavity, and a lower sub-crushing cavity.

Preferably, the generatrices of the conical surfaces of the fixed cone lining plate and the movable cone lining plate corresponding to the upper sub-crushing cavity form an engagement angle α₃, the generatrices of the conical surfaces of the fixed cone lining plate and the movable cone lining plate corresponding to the middle sub-crushing cavity form an engagement angle α₂, and the generatrices of the conical surfaces of the fixed cone lining plate and the movable cone lining plate corresponding to the lower sub-crushing cavity form an engagement angle α₁, and α₂>α₃>α₁.

Preferably, α₁=0.5α₃˜0.8α₃, and α₂=0.8α₃˜1.5α₃.

The portion of the crushing cavity near the discharge port forms a parallel sub-crushing cavity, and the working faces of the fixed cone lining plate and the movable cone lining plate opposite to each other in the region of the parallel sub-crushing cavity have generatrices parallel to each other.

Preferably, the cast-in alloy of the upper sub-crushing cavity has an elliptical or rectangular cross section that has a length-width ratio of 3:1˜5:1, and the length of the cross section is not greater than 50 mm; and/or,

the cast-in alloy of the middle sub-crushing cavity has a circular cross section in diameter not greater than 40 mm, or has an elliptical cross section that has a length-width ratio of 3:1-4:1, and the length of the cross section is not greater than 40 mm; and/or,

the cast-in alloy of the lower sub-crushing cavity has a circular cross section in diameter not greater than 30 mm; and/or,

the cast-in alloy of the parallel sub-crushing cavity has a circular cross section in diameter not greater than 20 mm.

A lining plate of multi-gradient structure-reinforced cone crusher, wherein, the working face of the lining plate of multi-gradient structure-reinforced cone crusher is provided with multiple sets of cast-in alloy, which are different in at least one of distribution density, maximum size of exposed surface, and shape of the cast-in alloy.

A design method of a lining plate of multi-gradient structure-reinforced cone crusher, comprising the following steps:

S1. establishing a geometric model of crushing cavity, a material crushing function and a material particle model, and simulating the material crushing process, to ascertain the difference in size-grade distribution and/or a characteristic wear curve of the lining plate in the material crushing process;

S2. arranging multiple sets of cast-in alloy that are different in at least one of distribution density, maximum size of exposed surface, and shape of the cast-in alloy on the working face of the lining plate, according to the difference in size-grade distribution and/or the characteristic wear curve of the lining plate.

Specifically, in the step S2, the working face of the lining plate is divided into a plurality of regions corresponding to an upper sub-crushing cavity, a middle sub-crushing cavity and a lower sub-crushing cavity respectively, according to the difference in size-grade distribution and/or the characteristic wear curve of the lining plate, and the step S2 comprises the following sub-steps:

S21. setting a maximum engagement angle αₘₐₓ according to the properties, size grade before crushing and size grade after crushing of the material;

S22. determining corresponding maximum filling density γₘₐₓ respectively according to the working condition of coarse crushing, medium crushing, and fine crushing;

S23. configuring the engagement angle αⱼ of the respective sub-crushing cavity so that it is not greater than the maximum engagement angle αₘₐₓ, and configuring the engagement angles α₃, α₂, α₁ of the upper sub-crushing cavity, the middle sub-crushing cavity, and the lower sub-crushing cavity to meet α₂>α₃>α₁.

Specifically, in the step S1, the difference in size-grade distribution in the material crushing process is ascertained through the following sub-steps:

setting the working parameters of the movable cone, and simulating the material crushing process by means of ADAMS and EDEM coupling, to find out the size-grade distribution of the material in the height direction in the crushing cavity.

The design method of the lining plate of multi-gradient structure-reinforced cone crusher ascertains the amount of wear of the lining plate caused by the material under a squeezing action in the crushing process with a wearing dynamics method, and simulates the material crushing process on the basis of multi-rigid dynamics and granular medium mechanics to ascertain the size-grade distribution of the material in the crushing cavity;

The shapes, dimensions, and distribution forms of the cast-in alloy in the lining plate of multi-gradient structure-reinforced cone crusher at different height positions are determined respectively according to the characteristic wear curve of the lining plate and the particle size distribution of the material in the crushing cavity;

With the lining plate of multi-gradient structure-reinforced cone crusher, the service life of the lining plate can be prolonged, the shape and structure of the crushing cavity can be kept consistent for a long time; in addition, the material can be crushed in a variety of ways, the size grade of the discharged material can be homogenized, and the crushing efficiency can be improved.

Preferably, the design method for the cast-in density of the cast-in alloy in the working surfaces of the fixed cone lining plate and the movable cone lining plate comprises the following steps: In the first step, the amount of wear of the lining plate in the crushing process is analyzed with a wearing dynamics method;

The calculation method of the amount of wear of the fixed cone lining plate and the movable cone lining plate comprises:

S31. calculating the amount of deformation of the material at cross section i in the crushing process according to the nutation angle and structural parameters of the crushing cone, and the value range of the engagement angle of the crushing cavity;

S32. calculating the stress on the working faces of the corresponding fixed cone lining plate and movable cone lining plate when the material is at a specific cross section in the crushing process according to the characteristic parameters of the material (e.g., elasticity modulus, compression strength, and loose coefficient);

S33. establishing a model of the amount of wear of corresponding lining plate in each turn of the movable cone on the movable cone lining plate in unit time at cross section i in the crushing cavity, according to the loose coefficient, initial deformation of the material at the specific cross section in the crushing cavity, and the deformation angle of the clamped material;

S34. ascertaining the amounts of wear of the working surfaces of the movable cone lining plate and the fixed cone lining plate respectively on the basis of the crushing load distribution in the height direction of the crushing cavity, and ascertaining a characteristic wear curve of the fixed cone lining plate and the movable cone lining plate.

In the second step, the material crushing process is simulated on the basis of multi-rigid dynamics and granular medium mechanics, to ascertain the size-grade distribution of the material in the crushing cavity;

Preferably, the method for analyzing the size-grade distribution of the material in the crushing cavity comprises:

S41. establishing a three-dimensional geometric model of the crushing cavity according to the geometric structural parameters of the crushing cavity;

S42. establishing a crushing function and a particle model of the material according to the particle size distribution before and after crushing;

S43. establishing a material crushing model by means of ADAMS and EDEM coupling;

S44. simulating the material crushing process with the working parameters of the movable cone and the material crushing function, to find out the size-grade distribution of the material in the crushing cavity in the height direction.

In the third step, the cast-in density of the alloy is designed;

Preferably, the spacing between adjacent sets of cast-in alloy in the fixed cone lining plate and the movable cone lining plate at positions corresponding to the upper crushing cavity, middle crushing cavity, lower crushing cavity, and parallel region are determined respectively, according to the characteristic wear curve of the lining plate and the particle size distribution of the material in the crushing cavity.

In the four steps, the shape and dimensions of the cast-in alloy are designed;

Preferably, the design method of the shape and dimensions of the cast-in alloy comprises:

S51. configuring the shape of the cast-in alloy to cylindrical, ellipsoid or cuboid shape;

S52. the cross-sectional dimensions of the cast-in alloy shall correspond to the granularity of the material before and after crushing, and shall be decreased sequentially from top to bottom along the fixed cone lining plate and the movable cone lining plate.

With the technical scheme described above, the following beneficial effects are attained with the present disclosure:

(1) A multi-stage tandem stepped inter-particle crushing cavity with an engagement angle decreased by stage is designed according to the requirement for the ratio of size reduction, so that the material is always in an inter-particle crushed state in the crushing process, and thereby the crushing efficiency is improved;

(2) Wear resistance design is carried out for the movable cone lining plate and the fixed cone lining plate under an uniform wearing principle on the basis of the wearing characteristic of the crushing cavity and the distribution of crushing load, so that the shape of the crushing cavity is kept unchanged essentially in the life cycle of the lining plate, i.e., the consistency of crushing performance is maintained;

(3) The wear-resistant cast-in alloy blocks are different in shape, structure, dimensions, cast-in density and layout in the working faces of the inter-particle crushing cavity from top to bottom in the height direction of the crushing cavity according to the particle size variation in the material crushing process, so that the material in different particle sizes can be squeezed, sheared, chopped, and inter-particle crushed quickly in the crushing cavity at different height positions;

(4) Local bumps and grooves may occur on the base material of the lining plate between the wear-resistant alloy blocks owing to the difference in wear resistance between the base material of the lining plate and the wear-resistant alloy, such local bumps and grooves are helpful for quick flow of the material in size smaller than the sizes of the grooves in the cavity, and such selective crushing can improve the crushing yield and homogenize the size grade of the discharged material.

### BRIEF DESCRIPTION OF DRAWINGS

FIG. 1 is a schematic structural diagram of the lining plate of multi-gradient structure-reinforced cone crusher;

FIG. 2 is shows the shape and layout of crushing cavity cast-in alloy in different regions in the present disclosure.

### REFERENCE NUMBERS

1—fixed cone lining plate; 2—movable cone lining plate; 31—upper sub-crushing cavity; 32—middle sub-crushing cavity; 33—lower sub-crushing cavity; 4—parallel sub-crushing cavity; 5—cast-in alloy of upper sub-crushing cavity; 6—cast-in alloy of middle sub-crushing cavity; 7—cast-in alloy of lower sub-crushing cavity; 8—cast-in alloy of parallel sub-crushing cavity.

### DETAILED DESCRIPTION OF THE EMBODIMENTS

Hereunder some embodiments of the present disclosure will be detailed with reference to the accompanying drawings. It should be understood that the embodiments described here are only provided to describe and explain the present disclosure rather than constitute any limitation to the present disclosure.

In the present disclosure, unless otherwise specified, the terms that denote the orientations are used as follows, for example: “top”, “bottom”, “left” and “right” usually refer to “top”, “bottom”, “left” and “right” as shown in the accompanying drawings; “inside” and “outside” refer to inside and outside in relation to the profiles of the components.

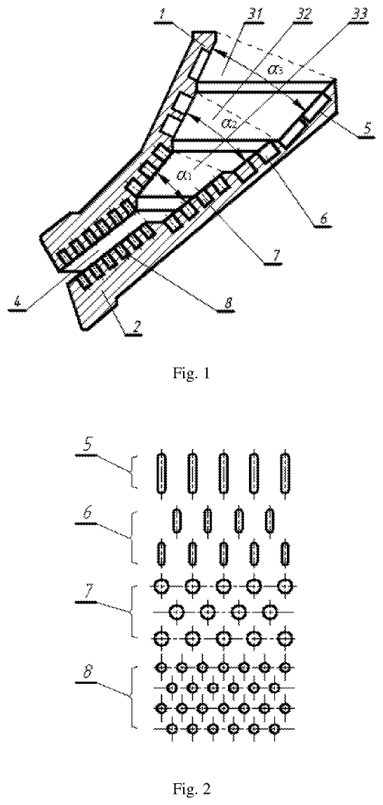

As shown in FIGS. 1 and 2, in a first aspect, the present disclosure provides a multi-gradient structure-reinforced cone crusher, which comprises a movable cone and a fixed cone arranged around the movable cone, and a crushing cavity formed in the radial space between the fixed cone and the movable cone, wherein the surfaces of the fixed cone and the movable cone that are opposite to each other are respectively provided with a fixed cone lining plate 1 and a movable cone lining plate 2, the working faces of the fixed cone lining plate 1 and the movable cone lining plate 2 that face the crushing cavity are provided with multiple sets of cast-in alloy, which are different in at least one of distribution density, maximum size of exposed surface and shape of cast-in alloy in a direction from the feed port to the discharge port.

The working faces of the fixed cone lining plate 1 and the movable cone lining plate 2 are stepped curve surfaces surrounding the rotating axis of the movable cone respectively, and the generatrix of the stepped curve surface comprises a plurality of broken line segments, so that the crushing cavity is formed into multiple levels of sub-crushing cavities, including an upper sub-crushing cavity 31, a middle sub-crushing cavity 32, and a lower sub-crushing cavity 33.

Wherein the generatrices of the conical surfaces of the fixed cone lining plate 1 and the movable cone lining plate 2 corresponding to the upper sub-crushing cavity 31 form an engagement angle α₃, the generatrices of the conical surfaces of the fixed cone lining plate 1 and the movable cone lining plate 2 corresponding to the middle sub-crushing cavity 32 form an engagement angle α₂, and the generatrices of the conical surfaces of the fixed cone lining plate 1 and the movable cone lining plate 2 corresponding to the lower sub-crushing cavity 33 form an engagement angle α₁, and α₂>α₃>α₁.

According to a preferred embodiment of the present disclosure, α₁=0.5α₃˜0.8α₃, and α₂=0.8α₃˜1.5α₃, the portion of the crushing cavity near the discharge port forms a parallel sub-crushing cavity 4, and the working faces of the fixed cone lining plate 1 and the movable cone lining plate 2 opposite to each other in the region of the parallel sub-crushing cavity 4 have generatrices parallel to each other.

Particularly, the working face of the lining plate of cone crusher is provided with multiple sets of cast-in alloy, which are different in at least one of distribution density, maximum size of exposed surface, and shape of cast-in alloy.

Wherein the cast-in alloy of the upper sub-crushing cavity 5 has an elliptical or rectangular cross section that has a length-width ratio of 3:1˜5:1, and the length of the cross section is not greater than 50 mm; and/or the cast-in alloy of the middle sub-crushing cavity 6 has a circular cross section in diameter not greater than 40mm, or has an elliptical cross section that has a length-width ratio of 3:1˜4:1, and the length of the cross section is not greater than 40 mm; and/or the cast-in alloy of the lower sub-crushing cavity 7 has a circular cross section in diameter not greater than 30 mm; and/or the cast-in alloy of the parallel sub-crushing cavity 8 has a circular cross section in diameter not greater than 20 mm.

As shown in FIGS. 1 and 2, in a second aspect, the present disclosure provides a design method of the above-mentioned lining plate of multi-gradient structure-reinforced cone crusher, wherein the structures of the sub-crushing cavities are designed according to the variation of the particle size of the material in the crushing process and the layered crushing conditions.

According to a preferred embodiment of the present disclosure, the upper sub-crushing cavity 31, the middle sub-crushing cavity 32, and the lower-sub crushing cavity 33 are designed through the following steps:

1) For metallic minerals with high hardness and toughness, the ratio of size reduction of the medium (or fine) cone crusher is set to 3˜5, the crushing cavity is in an linear shape, and the maximum engagement angle is set to αₘₐₓ≥25°;

2) The maximum filling density in upper sub-crushing cavity 31 and the middle sub-crushing cavity 32 is set to γₘₐₓ=0.65˜0.8; the maximum filling density in the lower sub-crushing cavity 33 is set to γₘₐₓ=0.75˜0.9;

3) The engagement angle of the upper sub-crushing cavity 31 is set to α₃=17°, the engagement angle of the middle sub-crushing cavity 32 is set to α₂=0.71α₃, then α₂=24°; the engagement angle of the lower sub-crushing cavity 33 is set to α₁=0.5α₃, then α₁=12°;

In a preferred embodiment of the present disclosure, the amount of wear of the fixed cone lining plate 1 and the movable cone lining plate 2 is calculated and analyzed through the following steps:

1) the amount of wear of the fixed cone lining plate 1 and the movable cone lining plate 2 corresponding to the cross section j of the crushing cavity at wearing time t is:

$${Δ}_{j} = c n {\int }_{0}^{ɛ} {σ}_{j} ( ɛ ) d ɛ$$

Wherein, ε—relative deformation of the material; σⱼ(ε)—surface load of the corresponding lining plate at the position of the cross section j of the crushing cavity, depending on the properties and relative deformation of the material to be crushed; n—swing frequency of the crushing cone; c—a scale coefficient related with the physical and mechanical properties of the material to be crushed and the lining plate; t—time of wearing.

2) The deformation of the squeezed material in initial thickness of h in the crushing process is:

$$\{ \begin{matrix}ɛ = {ɛ}_{0} [ cos ( θ - {θ}_{s} ) ] \\ {ɛ}_{0} = \frac{{ϕ}_{0}}{h} g \frac{{z}_{j} sin β + {r}_{j} cos β}{cos {γ}_{ρ}}\end{matrix}$$

Wherein, φ₀—nutation angle of the crushing cone; θ—deformation phase angle; θₛ—deformation phase angle when the material is clamped; rⱼ, zⱼ—radius and height of the cross section of calculation; β—included angle of the cross section of calculation in the horizontal direction with respect to the crushing cone; γ_{ρ}—engagement angle; ε₀—initial deformation of the material layer.

3) The stress-strain relationship of the squeezed material in the crushing process is:

$$σ ( ɛ ) = E \frac{1 - ∅}{∅ - ɛ} ɛ$$

Wherein, σ(ε)—surface load on the material; ∅—loose coefficient of material; σ₀—initial deformation resistance; E—elasticity modulus.

The amount of wear of the fixed cone lining plate 1 and the movable cone lining plate 2 may be expressed as:

$$Δ = c t n {D}_{0} ( 1 - ∅ ) {ɛ}_{0}^{2} {\int }_{0}^{{θ}_{s}} \frac{cos θ - cos {θ}_{s}}{∅ - {ɛ}_{0} ( cos θ - cos {θ}_{s} )} sin θ d θ$$

The characteristic wear curves of the fixed cone lining plate 1 and the movable cone lining plate 2 can be obtained according to the above amount of wear.

Specifically, the size-grade distribution of the material in the crushing cavity structure is simulated and analyzed on the basis of multi-rigid body dynamics and granular medium mechanics through the following steps:

1) A three-dimensional geometric model of the crushing cavity structure is established according to the geometric structural parameters of the crushing cavity structure;

2) A crushing function and a particle model of the material are established according to the particle size distribution before and after crushing;

3) A material crushing model is established by means of ADAMS and EDEM coupling;

4) The material crushing process is simulated with the working parameters of the movable cone and the material crushing function, to find out the size-grade distribution of the material in the crushing cavity at different height positions.

As shown in FIG. 2, the distribution density of the cast-in alloy of the upper sub-crushing cavity 5, the cast-in alloy of the middle sub-crushing cavity 6, the cast-in alloy of the lower sub-crushing cavity 7, and the cast-in alloy of the parallel sub-crushing cavity 8 are designed with the following method:

1) The spacing between the sets of cast-in alloy of the upper sub-crushing cavity 5 is 1˜1.5 times of the average particle diameter of the material in the region of the crushing cavity;

2) The spacing between the sets of cast-in alloy of the middle sub-crushing cavity 6 is 1˜1.5 times of the average particle diameter of the material in the region of the crushing cavity;

3) The spacing between the sets of cast-in alloy of the lower sub-crushing cavity 7 is 1˜1.5 times of the average particle diameter of the material in the region of the crushing cavity;

4) The spacing between the sets of cast-in alloy of the parallel sub-crushing cavity 8 is 1˜1.5 times of the average particle diameter of the crushed material.

Wherein the cross-sectional shapes and dimensions of the cast-in alloy of the upper sub-crushing cavity 5, the cast-in alloy of the middle sub-crushing cavity 6, the cast-in alloy of the lower sub-crushing cavity 7, and the cast-in alloy of the parallel sub-crushing cavity 8 are designed with the following method:

1) The length of the cast-in alloy of the upper sub-crushing cavity 5 is not greater than 50 mm, the length-width ratio is (3˜5):1, and the cross-section is in an elliptical or rectangular shape;

2) The cross section of the cast-in alloy of the middle sub-crushing cavity 6 is a circular cross section in diameter not greater than 40 mm, and/or is an elliptical cross section in length not greater than 40 mm with a length-width ratio of (3˜4):1;

3) The cross section of the cast-in alloy of the lower sub-crushing cavity 7 is a circular cross section in diameter not greater than 30 mm;

4) The cross section of the cast-in alloy of the parallel sub-crushing cavity 8 is a circular cross section in diameter not greater than 20 mm.

Some embodiments of the present disclosure are described above in detail with reference to the accompanying drawings, only for the purpose of explaining the technical scheme and technical features of the present disclosure and enabling those skilled in the art to understand the content of the present disclosure and the implementation. However, the embodiments of the present disclosure are not limited to the details in the embodiments described above. Various simple variations and modifications may be made to the technical schemes in the embodiments of the present disclosure within the scope of the technical ideal of the embodiments of the present disclosure, but all of those simple variations and modifications should be deemed as falling in the protection scope of the embodiments of the present disclosure. Various possible combinations of the embodiments of the present disclosure are not enumerated or detailed here to avoid unnecessary repetition.

1. A multi-gradient structure-reinforced cone crusher, comprising a movable cone and a fixed cone arranged around the movable cone, with a crushing cavity formed in the radial space between the fixed cone and the movable cone, wherein the surfaces of the fixed cone and the movable cone that are opposite to each other are respectively provided with a fixed cone lining plate and a movable cone lining plate, the working faces of the fixed cone lining plate and the movable cone lining plate that face the crushing cavity are provided with multiple sets of cast-in alloy, which are different in at least one of distribution density, maximum size of exposed surface and shape of the cast-in alloy in a direction from the feed port to the discharge port.

2. The multi-gradient structure-reinforced cone crusher of claim 1, wherein the working faces of the fixed cone lining plate and the movable cone lining plate are stepped curve surfaces surrounding the rotating axis of the movable cone respectively, and the generatrix of the stepped curve surface comprises a plurality of broken line segments, so that the crushing cavity is formed into multiple levels of sub-crushing cavities.

3. The multi-gradient structure-reinforced cone crusher of claim 2, wherein the multiple levels of sub-crushing cavities comprise an upper sub-crushing cavity, a middle sub-crushing cavity and a lower sub-crushing cavity;
wherein the generatrices of the conical surfaces of the fixed cone lining plate and the movable cone lining plate corresponding to the upper sub-crushing cavity form an engagement angle α₃, the generatrices of the conical surfaces of the fixed cone lining plate and the movable cone lining plate corresponding to the middle sub-crushing cavity form an engagement angle α₂, and the generatrices of the conical surfaces of the fixed cone lining plate and the movable cone lining plate corresponding to the lower sub-crushing cavity form an engagement angle α₁, and α₂>α₃>α₁.

4. The multi-gradient structure-reinforced cone crusher of claim 3, wherein α₁=0.5α₃˜0.8α₃, and α₂=0.8α₃˜1.5α₃.

5. The multi-gradient structure-reinforced cone crusher of claim 3, wherein the portion of the crushing cavity near the discharge port forms a parallel sub-crushing cavity, and the working faces of the fixed cone lining plate and the movable cone lining plate opposite to each other in the region of the parallel sub-crushing cavity have generatrices parallel to each other.

6. The multi-gradient structure-reinforced cone crusher of claim 5, wherein
the cast-in alloy of the upper sub-crushing cavity has an elliptical or rectangular cross section that has a length-width ratio of 3:1˜5:1, and the length of the cross section is not greater than 50 mm; and/or,
the cast-in alloy of the middle sub-crushing cavity has a circular cross section in diameter not greater than 40 mm, or has an elliptical cross section that has a length-width ratio of 3:1˜4:1, and the length of the cross section is not greater than 40 mm; and/or,
the cast-in alloy of the lower sub-crushing cavity has a circular cross section in diameter not greater than 30 mm; and/or,
the cast-in alloy of the parallel sub-crushing cavity has a circular cross section in diameter not greater than 20 mm.

7. A lining plate of multi-gradient structure-reinforced cone crusher, wherein the working face of the lining plate of multi-gradient structure-reinforced cone crusher is provided with multiple sets of cast-in alloy, which are different in at least one of distribution density, maximum size of exposed surface, and shape of the cast-in alloy.

8. A design method of a lining plate of multi-gradient structure-reinforced cone crusher, comprising:
S1. establishing a geometric model of crushing cavity, a material crushing function and a material particle model, and simulating the material crushing process, to ascertain the difference in size-grade distribution and/or a characteristic wear curve of the lining plate in the material crushing process;
S2. arranging multiple sets of cast-in alloy that are different in at least one of distribution density, maximum size of exposed surface, and shape of the cast-in alloy on the working face of the lining plate, according to the difference in size-grade distribution and/or the characteristic wear curve of the lining plate.

9. The design method of a lining plate of multi-gradient structure-reinforced cone crusher of claim 8, wherein in the step S2, the working face of the lining plate is divided into a plurality of regions corresponding to an upper sub-crushing cavity, a middle sub-crushing cavity and a lower sub-crushing cavity respectively, according to the difference in size-grade distribution and/or the characteristic wear curve of the lining plate, and the step S2 comprises the following sub-steps:
S21. setting a maximum engagement angle αₘₐₓ according to the properties, size grade before crushing and size grade after crushing of the material;
S22. determining corresponding maximum filling density γₘₐₓ respectively according to the working condition of coarse crushing, medium crushing, and fine crushing;
S23. configuring the engagement angle αⱼ of the respective sub-crushing cavity so that it is not greater than the maximum engagement angle αₘₐₓ, and configuring the engagement angles α₃, α₂, α₁ of the upper sub-crushing cavity, the middle sub-crushing cavity, and the lower sub-crushing cavity to meet α₂>α₃>α₁.

10. The design method of a lining plate of multi-gradient structure-reinforced cone crusher of claim 8, wherein in the step S1, the difference in size-grade distribution in the material crushing process is ascertained through the following sub-steps:
setting the working parameters of the movable cone, and simulating the material crushing process by means of ADAMS and EDEM coupling, to find out the size-grade distribution of the material in the height direction in the crushing cavity.
